(19) United States
(12) Patent Application Publication
(10) Pub. No.: US 2017/0017545 A1
(43) Pub. Date: Jan. 19, 2017

(54) ERROR CORRECTION DEVICE, SEMICONDUCTOR STORAGE DEVICE, AND ERROR CORRECTION METHOD

(71) Applicant: RENESAS ELECTRONICS CORPORATION, TOKYO (JP)

(72) Inventor: AKIRA TANABE, TOKYO (JP)

(21) Appl. No.: 15/144,607

(22) Filed: May 2, 2016

(30) Foreign Application Priority Data
Jul. 14, 2015 (JP) 2015-140525

(51) Int. Cl. G06F 11/10; H03M 13/15; G11C 29/52

(52) U.S. Cl. CPC G06F 11/1068; G11C 29/52; H03M 13/154; H03M 13/152

(57) ABSTRACT

There is provided an error correction device with a simple configuration and a high correction capability. An error correction device which can perform c (c<n) error corrections on n-bit encoded data containing a parity bit includes an assumption data setting circuit for setting a plurality of assumption data, containing c error bits and (n−c) or fewer erasure bits, by assuming data of an erasure bit, and a decoding circuit which calculates a syndrome for each of the assumption data set by the assumption data setting circuit and performs decoding based on a calculation result and the parity bit.

### CROSS-REFERENCE TO RELATED APPLICATIONS

The disclosure of Japanese Patent Application No. 2015-140525 filed on Jul. 14, 2015 including the specification, drawings and abstract is incorporated herein by reference in its entirety.

### BACKGROUND

The present disclosure relates to an error correction device, and particularly to an error correction device using an error correction code containing a parity bit.

There is known an error correction technique as a technique for correctly decoding original data at the time of reading digital information stored in a memory or the like and receiving transmitted digital information.

In the error correction technique, redundancy is provided by encoding original data, and an error of the data is detected and corrected utilizing the redundancy. For example, a Hamming code and a BCH (Bose-Chaudhuri-Hocquenghem) code are known as error correction codes (the Art of Error Correcting Coding, John Wiley & Sons, 2002, pp 103, pp 55-56 (Non-patent Document 1)).

Japanese Unexamined Patent Publication No. 2003-115197 (Patent Document 1) discloses another error correction code. More specifically, a plurality of threshold values are set for a cell resistance value in reading the resistance value of a memory cell in an MRAM (Magnetoresistive Random Access Memory), thereby providing a cell resistance value for determining an erasure state besides a cell resistance value for determining “0” or “1”. It is shown that a Reed-Solomon code is used in the encoding/decoding, thereby performing correction in consideration of not only the inversion state of data but also the erasure state.

### SUMMARY

However, the Reed-Solomon code has a high correction capability, but has high redundancy, and has complicated processing as compared to the Hamming code and the BCH code, which takes time for decoding processing. This does not enable high-speed data reading, and particularly makes it difficult to apply the Reed-Solomon code to a main memory or the like of a computer to be accessed in real time. Further, complicated decoding processing disadvantageously increases a circuit configuration for implementing error correction.

On the other hand, error correction using the Hamming code or some BCH codes enables high-speed decoding processing, but does not have a high correction capability, which cannot significantly decrease an error occurrence probability.

The present disclosure has been made to solve the above problems, and an object thereof is to provide an error correction device, a semiconductor storage device, and an error correction method with a simple configuration and a high correction capability.

The other problems and novel features will become apparent from the description of this specification and the accompanying drawings.

An error correction device according to one embodiment is an error correction device which can perform c (c<n) error corrections on n-bit encoded data containing a parity bit. The error correction device includes an assumption data setting circuit for setting a plurality of assumption data, containing c error bits and (n−c) or fewer erasure bits, by assuming data of an erasure bit, and a decoding circuit which calculates a syndrome for each of the assumption data set by the assumption data setting circuit and performs decoding based on a calculation result and the parity bit.

According to the error correction device according to the one embodiment, it is possible to improves an error correction capability using an error correction code with a simple configuration.

### BRIEF DESCRIPTION OF THE DRAWINGS

FIG. 1 is a diagram for explaining data encoding using a Hamming code.

FIGS. 2A and 2B are diagrams for explaining an error detection method and an error correction method for data encoded by the Hamming code.

FIG. 3 is a diagram for explaining a data error detection method using an extended Hamming code.

FIGS. 4A and 4B are diagrams for explaining an error correction method for data encoded by the Hamming code and containing 1-bit erasure and 1-bit inversion according to a first embodiment.

FIG. 5 is a diagram showing a configuration example of an error correction device according to the first embodiment.

FIG. 6 is a diagram showing a configuration example of a decoding circuit according to a modification of the first embodiment.

FIG. 7 is a diagram showing a configuration example of an erasure position decision circuit according to the first embodiment.

FIG. 8 is a diagram showing a configuration example of an assumption data setting circuit according to the first embodiment.

FIG. 9 is a diagram showing a configuration example of a semiconductor storage device according to the first embodiment.

FIG. 10 is a diagram showing a circuit configuration example of an erasure determination circuit according to the first embodiment.

FIG. 11 is a diagram showing a probability distribution with respect to the resistance value of a memory cell according to the first embodiment.

FIGS. 12A to 12C are diagrams for comparing error occurrence probabilities under different conditions according to the first embodiment.

FIG. 13 is a diagram for explaining an error correction method for data encoded by the Hamming code and containing 2-bit erasure according to the first embodiment.

FIG. 14 is a diagram showing a configuration example of an error correction device according to a modification of the first embodiment.

FIG. 15 is a diagram showing a probability distribution with respect to the resistance value of a memory cell according to a second embodiment.

FIG. 16 is a diagram showing a probability distribution with respect to the resistance value of the memory cell according to the second embodiment.

FIG. 17 is a diagram for explaining an error correction method for a Hamming code containing 3-bit erasure according to the second embodiment.

FIG. 18 is a diagram showing a circuit configuration example of an erasure determination circuit according to the second embodiment.

FIG. 19 is a diagram for explaining an example of data encoding using a BCH code.

FIGS. 20A and 20B are diagrams for explaining an error detection method and an error correction method for data encoded by the BCH code.

FIGS. 21A and 21B are diagrams for explaining an error correction method for data encoded by the BCH code and containing 1-bit erasure and 2-bit inversion according to a third embodiment.

### DETAILED DESCRIPTION

Hereinafter, various embodiments of the present invention will be described in detail with reference to the drawings. The same or equivalent sections in the drawings are denoted by the same reference numerals, and their description will not be repeated.

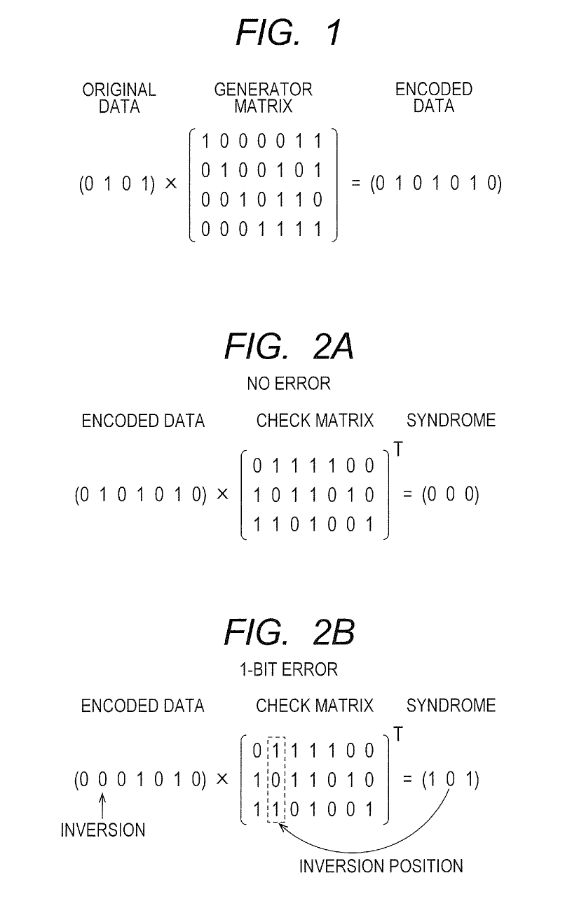

FIG. 1 is a diagram for explaining data encoding using a Hamming code. By way of example, the case of a (7, 4) Hamming code will be described. As shown in FIG. 1, 4-bit original data is multiplied by a generator matrix with 4 rows and 7 columns, thereby obtaining a (7, 4) Hamming code (encoded data) including three redundant bits.

FIGS. 2A and 2B are diagrams for explaining an error detection method and an error correction method for data encoded by the Hamming code. The encoded data is multiplied by the transposed matrix of a check matrix, thereby obtaining a syndrome. Referring to FIG. 2A, if the encoded data does not contain an error, all elements of the syndrome are 0. On the other hand, referring to FIG. 2B, if the encoded data contains 1-bit inversion, not all elements of the syndrome are 0. Thus, in the error detection method using the Hamming code, by calculating the syndrome, it is possible to determine whether or not the encoded data contains an error.

Referring to FIG. 2B, in the error correction method using the Hamming code, if the encoded data contains 1-bit inversion as an error; by comparing the syndrome with the check matrix, it is possible to determine which column contains the error. However, the Hamming code has the capability of inversion correction of up to one bit. Therefore, if the encoded data contains inversion of two bits or more, in the error correction method using the Hamming code, even by comparing the syndrome with the check matrix, it is not possible to determine which column contains the error and how many error bits are contained.

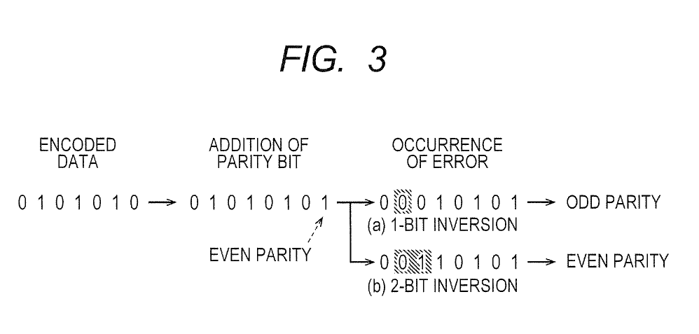

FIG. 3 is a diagram for explaining a data error detection method using an extended Hamming code. Referring to FIG. 3, one parity bit is added to the (7, 4) Hamming code. By way of example, a case in which the parity bit is set to 1 so that the parity becomes even will be described. Assume that the encoded data is subjected to some physical effect and an error occurs.

Referring to (a) of FIG. 3, if the encoded data contains 1-bit inversion, the parity is odd.

On the other hand, referring to (b) of FIG. 3, if the data contains 2-bit inversion, the parity is even.

Therefore, in the error detection method using the extended Hamming code, by comparing the parity of the original encoded data with the parity of the encoded data containing the error (parity check), it is possible to check whether the encoded data containing the error contains 1-bit inversion or 2-bit inversion.

### First Embodiment

### [Correction of 1-Bit Erasure and 1-Bit Inversion Using Hamming Code]

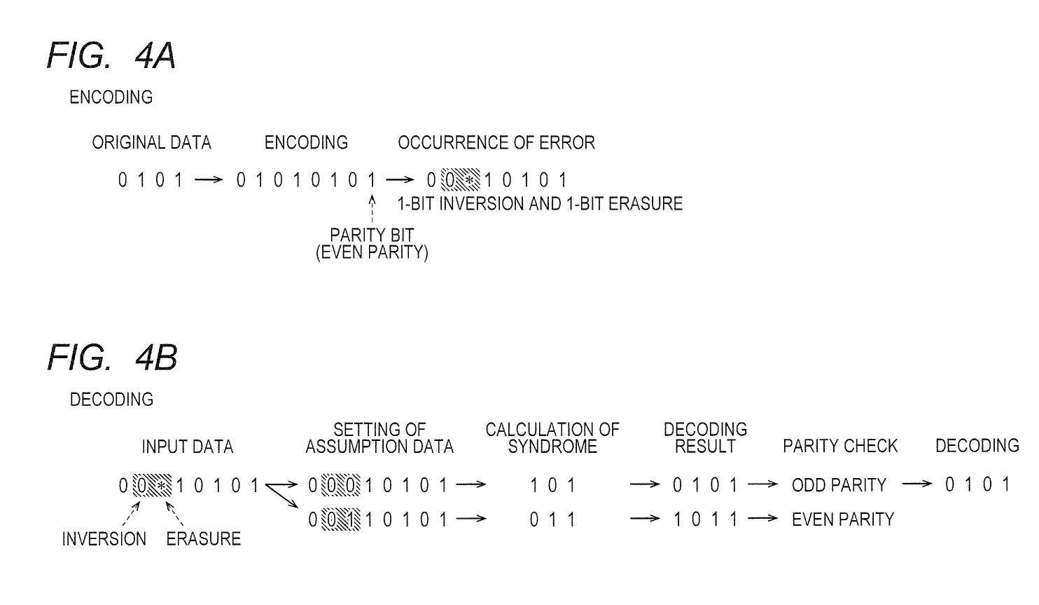

FIGS. 4A and 4B are diagrams for explaining an error correction method for data encoded by the Hamming code and containing 1-bit erasure and 1-bit inversion according to the first embodiment.

Referring to FIG. 4A, by way of example, 4-bit original data is encoded into a (8, 4) Hamming code. At this time, a parity bit is set so that the parity becomes even. Assume that an error occurs in the encoded data, which brings about encoded data containing 1-bit inversion and 1-bit erasure. The term “erasure” refers to a state of not being able to determine whether data is in a normal state “0” or an inversion state “1”.

Referring to FIG. 4B, to decode the original data, assumption data for a case where the erasure bit of input data is “0” and assumption data for a case where the erasure bit is “1” are set. At this time, it is unknown whether or not inversion is contained in each assumption data.

Next, in the error correction method according to the first embodiment, a syndrome is calculated for each set assumption data, thereby to decode the original data. At this time, since not all elements of the syndrome are 0 in each assumption data, it can be seen that inversion of one bit or more is contained.

Next, a parity check is performed on each set assumption data. Since the original encoded data is set so that the parity becomes even, it can be determined that 1-bit inversion is contained if the parity of the assumption data is odd and 2-bit inversion is contained if the parity of the assumption data is even. In this embodiment, it is determined that the assumption data of odd parity which is within the range of the error correction capability of the Hamming code is correct assumption data. Then, the result decoded using the applicable assumption data is adopted.

Further, there might be a case where inversion is not contained and 1-bit erasure or 2-bit erasure is contained in the input data. In this case, assumption data for a case where the erasure bit is “0” and assumption data for a case where the erasure bit is “1” are set, and a result decoded using the assumption data where each element of the syndrome is 0 is adopted.

According to the first embodiment, it is possible to improve the correction capability of the error correction code with a simple method.

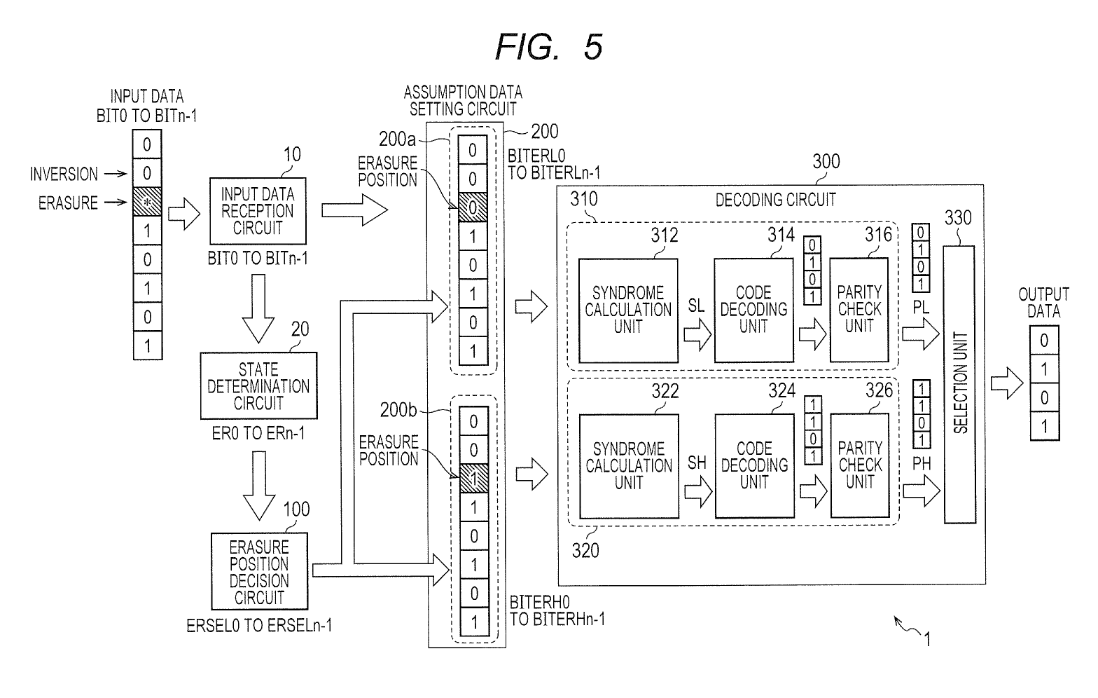

FIG. 5 is a diagram showing a configuration example of an error correction device according to the first embodiment. By way of example, the error correction device 1 which implements error correction using the Hamming code will be described. The error correction device 1 includes an input data reception circuit 10, a state determination circuit 20, an erasure position decision circuit 100, an assumption data setting circuit 200, and a decoding circuit 300.

As an example of data inputted to the error correction device 1 according to the first embodiment, n-bit data encoded using the Hamming code is used.

The input data reception circuit 10 receives and stores n-bit input data BIT0 to BITn-1 inputted to the error correction device, and outputs the input data to the state determination circuit 20. For example, the input data reception circuit 10 may be configured with a buffer or a register.

The state determination circuit 20 determines whether each bit of the input data BIT0 to BITn-1 inputted from the input data reception circuit 10 is in an erasure state. For example, if the input data BITk (k=0, 1, . . . , n-1) is in the erasure state, the state determination circuit 20 outputs erasure state determination data ERk as 1. Further, if the input data BITk is not in the erasure state (is in the normal state or the inversion state), the state determination circuit 20 outputs the erasure state determination data ERk as 0.

The erasure position decision circuit 100 decides the position of the erasure bit, based on the erasure state determination data ER0 to ERn-1 inputted from the state determination circuit 20. More specifically, if a plurality of bits indicating the erasure state are contained in the erasure state determination data ER0 to ERn-1, the erasure position decision circuit 100 outputs a predetermined number of bits as erasure bits, in accordance with predetermined priority order.

For example, if the erasure state determination data ERk indicates the erasure state and is set as the erasure bit due to high priority, the erasure position decision circuit 100 outputs erasure position decision data ERSELk as 1. If the erasure state determination data ERk does not indicate the erasure state, the erasure position decision circuit 100 outputs the erasure position decision data ERSELk as 0.

The predetermined number of bits set as erasure bits may be determined in accordance with the erasure correction capability of the error correction code.

In the case where the input data BIT0 to BITn-1 are serially inputted to the input data reception circuit 10 and the erasure bit position can be specified at the time of input, the error correction device 1 does not need to include the erasure position decision circuit 100.

Based on the erasure position decision data ERSEL0 to ERSELn-1 inputted from the erasure position decision circuit 100 and the input data BIT0 to BITn-1 inputted from the input data reception circuit 10, the assumption data setting circuit 200 sets assumption data for a case where the erasure bit is “0” and assumption data for a case where the erasure bit is “1”.

The assumption data setting circuit 200 includes assumption data setting units 200a, 200b. For example, the assumption data setting unit 200a sets the input data BITk corresponding to the erasure position decision data ERSELk “0” (not the erasure bit) to assumption data BITERLk. On the other hand, the assumption data setting unit 200a sets the input data BITk corresponding to the erasure position decision data ERSELk “1” (the erasure bit) to assumption data BITERLk (“0”). The assumption data setting unit 200b sets the input data BITk corresponding to the erasure position decision data ERSELk “0” to assumption data BITERHk. On the other hand, the assumption data setting unit 200b sets the input data BITk corresponding to the erasure position decision data ERSELk “1” to assumption data BITERHk (“1”).

In the case of setting a plurality of bits as erasure bits in the erasure position decision circuit 100, assumption data setting units whose number is a power of the number of erasure bits may be provided, and each assumption data setting unit may output different assumption data.

The decoding circuit 300 decodes the original data, based on the assumption data BITERL0 to BITERLn-1 and BITERH0 to BITERHn-1 inputted from the assumption data setting circuit 200.

The decoding circuit 300 according to this embodiment includes a decoding unit 310, a decoding unit 320, and a selection unit 330.

The decoding unit 310 includes a syndrome calculation unit 312, a code decoding unit 314, and a parity check unit 316.

The decoding unit 320 includes a syndrome calculation unit 322, a code decoding unit 324, and a parity check unit 326.

In the decoding unit 310, the syndrome calculation unit 312 calculates a syndrome SL, using the assumption data BITERL0 to BITERLn-1 set in the assumption data setting unit 200a.

The code decoding unit 314 decodes data based on the calculation result. The parity check unit 316 performs a parity check on the assumption data BITERL0 to BITERLn-1, and outputs the decoding result and parity information PL (the result of the parity check) to the selection unit 330.

The parity check unit 316 may be disposed before the syndrome calculation unit 312, or may be disposed between the syndrome calculation unit 312 and the code decoding unit 314. Alternatively, the parity check unit 316 may be arranged in parallel with the syndrome calculation unit 312 and the code decoding unit 314 for concurrent operation.

In the decoding unit 320, the syndrome calculation unit 322 calculates a syndrome SH, using the assumption data BITERH0 to BITERHn-1 set in the assumption data setting unit 200b.

The code decoding unit 324 decodes data based on the calculation result. The parity check unit 326 performs a parity check on the assumption data BITERH0 to BITERHn-1, and outputs the decoding result and parity information PH to the selection unit 330.

In the first embodiment, in the decoding circuit 300, the decoding units are provided in accordance with the number of assumption data set by the assumption data setting circuit 200. This is to parallelly operate decoding processing which takes processing time and to enable high-speed decoding. In another aspect, the decoding circuit 300, without having a plurality of decoding units, may be configured to operate with a single unit.

The selection unit 330 selects parity information corresponding to predetermined parity information from the parity information PL, PH inputted from the parity check units 316, 326, and selects the decoding result corresponding to the selected one of the parity information PL, PH. More specifically, the selection unit 330 selects parity information indicating odd parity which is within the range of the error correction capability of the Hamming code, and outputs the decoding result corresponding to the odd parity. On the other hand, the decoding result corresponding to parity information indicating even parity is beyond the range of the error correction capability of the Hamming code; accordingly, the selection unit 330 does not output the decoding result.

Thus, it is possible to achieve the error correction device that improves the original correction capability of the error correction code with a simple configuration.

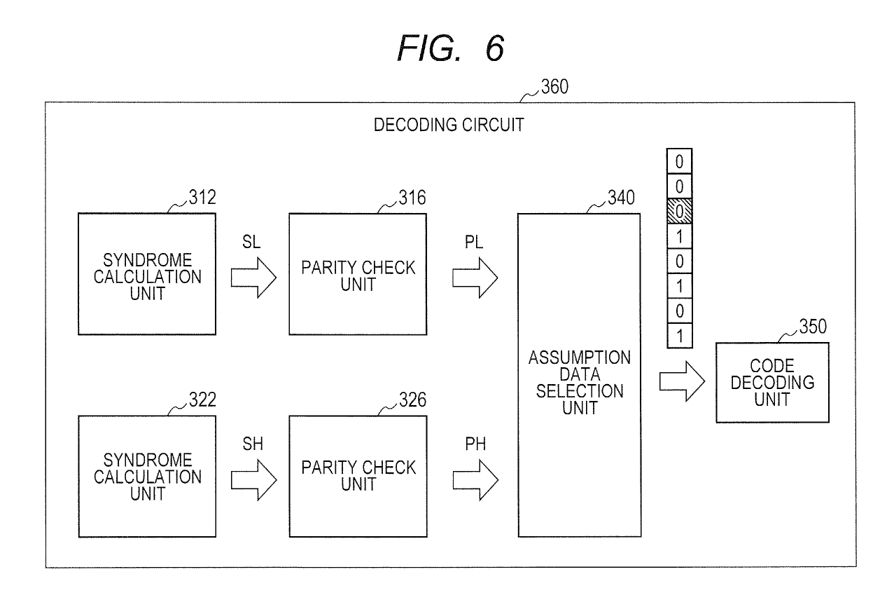

FIG. 6 is a diagram showing a configuration example of a decoding circuit according to a modification of the first embodiment. As shown in FIG. 6, a decoding circuit 360 may be used as a modification of the decoding circuit 300.

The decoding circuit 360 includes syndrome calculation units 312, 322, parity check units 316, 326, an assumption data selection unit 340, and a code decoding unit 350.

The syndrome calculation unit 312 calculates the syndrome SL, using the assumption data BITERL0 to BITERLn-1 set in the assumption data setting unit 200a.

The parity check unit 316 performs a parity check on the assumption data BITERL0 to BITERLn-1, and outputs the parity information PL and the syndrome SL to the assumption data selection unit 340.

The syndrome calculation unit 322 calculates the syndrome SH, using the assumption data BITERH0 to BITERHn-1 set in the assumption data setting unit 200b.

The parity check unit 326 performs a parity check on the assumption data BITERH0 to BITERHn-1, and outputs the parity information PH and the syndrome SH to the assumption data selection unit 340.

The assumption data selection unit 340 checks the syndromes SL, SH. If there exists assumption data where either the syndrome SL or the syndrome SH is 0, the assumption data selection unit 340 determines that the assumption data is correct assumption data, and outputs the assumption data along with the syndrome calculation result to the code decoding unit 350.

The code decoding unit 350 decodes a decoding result, based on the inputted assumption data and syndrome, and outputs the result.

On the other hand, if both syndromes SL and SH are not 0, the assumption data selection unit 340 selects parity information corresponding to predetermined parity information from the parity information PL, PH, and outputs the assumption data and the syndrome corresponding to the selected one of the parity information PL, PH to the code decoding unit 350. More specifically, in this example, the assumption data selection unit 340 outputs the assumption data and the syndrome corresponding to parity information indicating odd parity which is within the range of the error correction capability of the Hamming code.

The code decoding unit 350 decodes a decoding result, based on the inputted assumption data and syndrome, and outputs the result.

In this example, by selecting correct assumption data beforehand, it is possible to omit a plurality of assumption data decoding processes. As a result, it is possible to attain space saving of a circuit configuration and implement high-speed processing.

Next, the operation of the error correction device 1 will be described using a specific example of data inputted to the input data reception circuit 10. For example, assume that an error occurs in the (8, 4) Hamming code (01010101) obtained by setting the parity bit to the original data (0101) so that the parity becomes even and the input data BIT0 to BIT7 (00*10101) is inputted to the input data reception circuit 10. In the input data, the second bit is inverted, and the third bit is erased.

The state determination circuit 20 determines that the third bit of the input data BIT0 to BIT7 (00*10101) is in the erasure state, and outputs the erasure state determination data ER0 to ER7 (00100000) to the erasure position decision circuit 100.

The erasure position decision circuit 100 decides the erasure state determination data ER2 as the erasure bit, based on the predetermined priority order, and outputs the erasure position decision data ERSEL0 to ERSEL7 (00100000) to the assumption data setting circuit 200.

The assumption data setting circuit 200 sets assumption data, based on the input data BIT0 to BIT7 received by the input data reception circuit 10 and the erasure position decision data ERSEL0 to ERSEL7.

In this example, the assumption data setting unit 200a sets the assumption data BITERL0 to BITERL7 (00010101) in which the erasure bit of the input data BIT0 to BIT7 (00*10101) is “0”. The assumption data setting unit 200b sets the assumption data BITERH0 to BITERH7 (00110101) in which the erasure bit of the input data BIT0 to BIT7 (00*10101) is “1”. Further, the assumption data setting circuit 200 outputs the set data to the decoding circuit 300.

The syndrome calculation unit 312 calculates the syndrome SL, using the assumption data BITERL0 to BITERL7 (00010101).

The code decoding unit 314 compares the syndrome SL with the check matrix, and decodes the decoding result (0101).

The parity check unit 316 determines that the parity of the assumption data BITERL0 to BITERL7 (00010101) is odd parity, and outputs the decoding result (0101) and the parity information PL indicating the odd parity to the selection unit 330.

On the other hand, the syndrome calculation unit 322 calculates the syndrome SH, using the assumption data BITERH0 to BITERH7 (00110101).

The code decoding unit 324 compares the syndrome SH with the check matrix, and decodes the decoding result (1101).

The parity check unit 326 determines that the parity of the assumption data BITERH0 to BITERH7 (00110101) is even parity, and outputs the decoding result (1101) and the parity information indicating the even parity PH to the selection unit 330.

The selection unit 330 selects the decoding result (0101) corresponding to the odd parity PL which is within the range of the error correction capability of the Hamming code from the inputted decoding results (0101), (1101), and outputs the decoding result (0101). On the other hand, the decoding result (1101) corresponding to the even parity PH is beyond the range of the error correction capability of the Hamming code; accordingly, the selection unit 330 does not output the decoding result (1101).

Next, the case of using the decoding circuit 360 in place of 300 will be described. The overlapping sections will not be described in detail.

The syndrome calculation unit 312 calculates the syndrome SL, using the assumption data BITERL0 to BITERL7 (00010101).

The parity check unit 316 determines that the parity of the assumption data BITERL0 to BITERL7 (00010101) is odd parity, and outputs the syndrome SL, the assumption data BITERL0 to BITERL7 (00010101), and the parity information PL indicating the odd parity to the assumption data selection unit 340.

The syndrome calculation unit 322 calculates the syndrome SH, using the assumption data BITERH0 to BITERH7 (00110101).

The parity check unit 326 determines that the parity of the assumption data BITERH0 to BITERH7 (00110101) is even parity, and outputs the syndrome SH, the assumption data BITERH0 to BITERH7 (00110101), and the parity information PH indicating the even parity to the assumption data selection unit 340.

The assumption data selection unit 340 checks the syndromes SL, SH. If there exists assumption data where each element of either the syndrome SL or the syndrome SH is 0, the assumption data selection unit 340 determines that the assumption data is correct assumption data, and outputs the syndrome calculation result and the assumption data to the code decoding unit 350.

The code decoding unit 350 decodes a decoding result, based on the inputted assumption data and syndrome, and outputs the result.

If not all elements of the syndrome are 0 in each syndrome SL, SH, the assumption data selection unit 340 selects the odd parity PL which is within the range of the error correction capability of the Hamming code from the parity information PL, PH. Then, the assumption data selection unit 340 outputs the assumption data BITERL0 to BITERL7 (00010101) corresponding to the parity information PL and the syndrome SL to the code decoding unit 350.

The code decoding unit 350 decodes data, based on the inputted assumption data BITERL0 to BITERL7 (00010101) and syndrome SL, and outputs the decoding result (0101).

As the assumption data selection unit 340 selects correct assumption data beforehand, it is possible to omit a decoding process. As a result, it is possible to attain the space saving of the circuit configuration and implement high-speed processing.

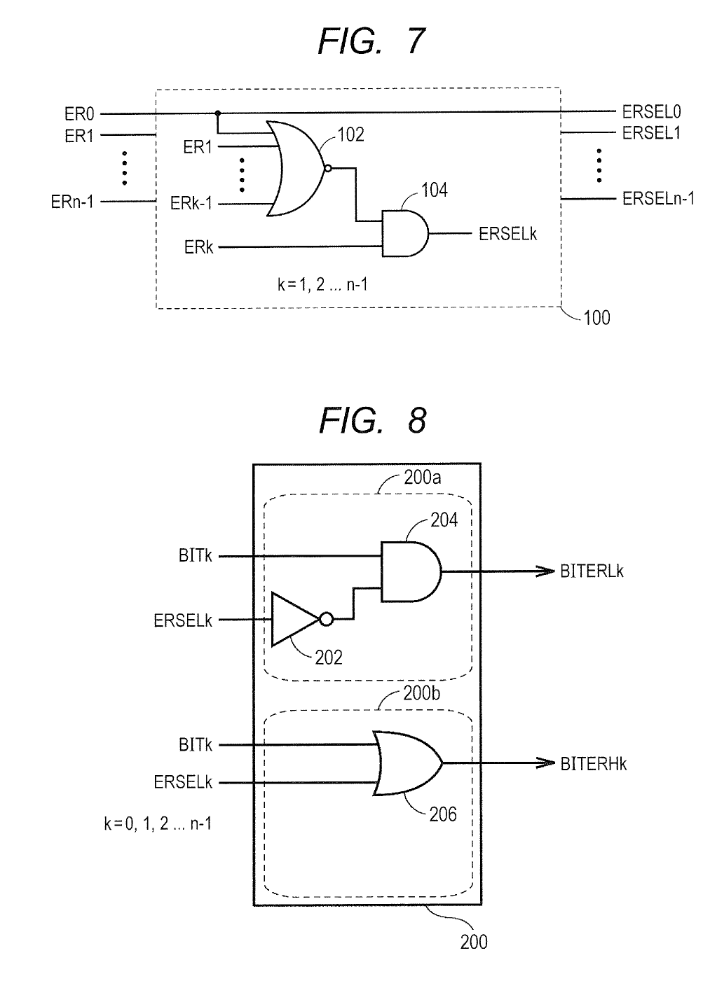

FIG. 7 is a diagram showing a configuration example of the erasure position decision circuit according to the first embodiment. As shown in FIG. 7, the erasure position decision circuit 100 decides the position of the erasure bit, based on the erasure state determination data ER0 to ERn-1 inputted from the state determination circuit 20. More specifically, the erasure position decision circuit 100 includes a NOR gate 102 and an AND gate 104.

The NOR gate 102 receives the input of the erasure state determination data ER0 to ERn-1, and outputs a NOR logical operation result to the AND gate 104.

The AND gate 104 receives the output of the NOR gate 102 and the input of the erasure state determination data ERk, and outputs the AND logical operation result.

By way of example, assume that the priority of the erasure state determination data ER0 is the highest, the priority of ER1, ER2, . . . decreases in order, and the priority of ERn-1 is the lowest.

For example, even if the erasure state determination data ERk indicates the erasure state “1”, if the erasure state determination data ERk-1 (k≧2) indicates the erasure state “1”,the output of the NOR gate 102 is “0”. As a result, the erasure position decision data ERSELk which is the output of the AND gate 104 is “0”.

On the other hand, if the erasure state determination data ERk indicates the erasure state “1” and all erasure state determination data that has higher priority than ERk indicates the non-erasure state “0”, the output of the NOR gate 102 is “1”. As a result, the erasure position decision data ERSELk is “1”.

Since the erasure position decision circuit 100 according to the first embodiment has a configuration in which only the erasure state determination data ERk that indicates the erasure state and has the highest priority in the inputted erasure state determination data ER0 to ERn-1 is set as the erasure bit, it is possible to specify the position of the erasure bit in the input data.

In the first embodiment, only one bit of the erasure state determination data ER0 to ERn-1 is set as the erasure bit; however, in another aspect, a predetermined number of bits may be treated as erasure bits. For example, the number of bits according to the erasure correction capability of the error correction code may be set as erasure bits.

FIG. 8 is a diagram showing a configuration example of the assumption data setting circuit according to the first embodiment. As shown in FIG. 8, the assumption data setting circuit 200 includes the assumption data setting unit 200a and the assumption data setting unit 200b. The assumption data setting unit 200a includes an inverter 202 and an AND gate 204. The assumption data setting unit 200b includes an OR gate 206.

The AND gate 204 receives the input data BITk inputted from the input data reception circuit 10 and the input of the erasure position decision data ERSELk inverted through the inverter 202, and sets the AND logical operation result as the assumption data BITERLk.

The OR gate 206 receives the input data BITk inputted from the input data reception circuit 10 and the input of the erasure position decision data ERSELk, and sets the OR logical operation result as the assumption data BITERHk.

In the first embodiment, in the erasure position decision data ERSEL0 to ERSELn-1, only one bit determined beforehand by the erasure position decision circuit 100 is the erasure bit “1”, and the other (n-1) bits are the non-erasure bits “0”.

For example, if the kth erasure position decision data ERSELk is the non-erasure bit “0”, the AND gate 204 and the OR gate 206 output the input data BITk as it is; therefore, the assumption data BITERLk is equal to the assumption data BITERHk.

On the other hand, if the kth ERSELk is the erasure bit “1”, BITk does not exist; therefore, the assumption data BITERLk is 0, and the assumption data BITERHk is 1.

Thus, it is possible to set the assumption data in which the erasure bit is assumed to be “0” and the assumption data in which the erasure bit is assumed to be “1”.

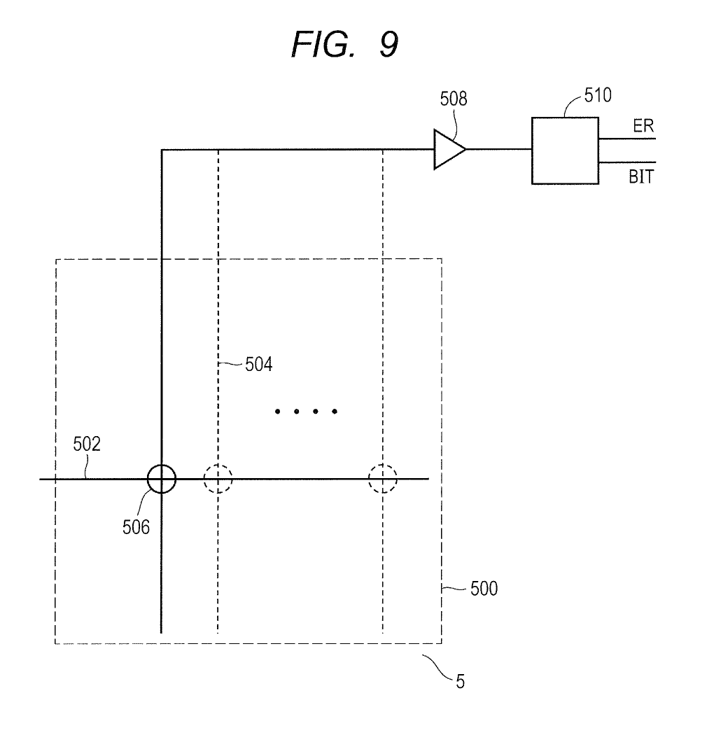

FIG. 9 is a diagram showing a semiconductor storage device according to the first embodiment. Referring to FIG. 9, the semiconductor storage device 5 includes a memory cell array 500 in which memory cells 506 are integrally arranged in a matrix. The memory cell array 500 includes a word line 502 arranged corresponding to each row of the memory cells 506 and a bit line 504 arranged corresponding to each column of the memory cells 506. The bit line 504 may be configured with a plate line. The semiconductor storage device 5 further includes a sense amplifier 508 for amplifying and reading data from the bit line 504 at the time of reading data of an addressed memory cell 506 and an erasure determination circuit 510 which receives the output of the sense amplifier as a current value or a voltage value and detects the state of the bit stored in the memory cell 506.

The memory cell 506 may be either volatile or nonvolatile memory element, such as an SRAM (Static Random Access Memory), a DRAM (Dynamic Random Access Memory), a flash memory, an ReRAM (Resistance Random Access Memory), an MRAM, or an FeRAM (Ferroelectric Random Access Memory).

The data of the memory cell 506 can be, for example, the resistance value, voltage value, charge amount, or current amount of the memory cell 506.

The erasure determination circuit 510 is not disposed for each bit line 504, but erasure determination circuits whose number is equivalent to the number of data that the memory cell array can simultaneously output are disposed for the memory cell array 500. Thus, by sharing the erasure determination circuit 510 among a plurality of bit lines 504, it is possible to minimize variation, in determining the state of the bit stored in the memory cell 506, which occurs in the case of providing a plurality of erasure determination circuit 510.

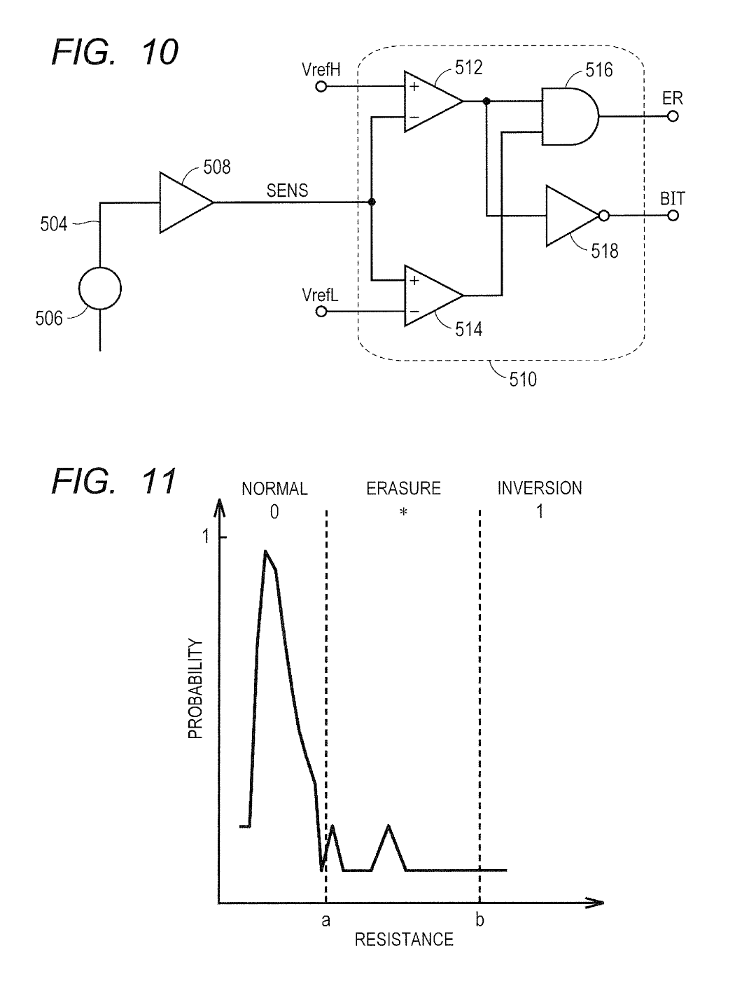

FIG. 10 is a diagram showing the circuit configuration of the erasure determination circuit according to the first embodiment. Referring to FIG. 10, the erasure determination circuit 510 determines the state of the bit stored in the memory cell 506.

The erasure determination circuit 510 according to the first embodiment includes comparators 512, 514, an AND gate 516, and an inverter 518. The sense amplifier 508 outputs a voltage SENS according to the data level of the memory cell 506 read from the bit line 504. The erasure determination circuit 510 compares the voltage SENS with reference voltages VrefH, VrefL inputted to the comparators 512, 514, thereby detecting the state of the bit stored in the memory cell 506. Assume that the voltage value VrefH>VrefL.

More specifically, if the voltage SENS outputted from the sense amplifier 508 is lower than the reference voltage VrefH inputted to the comparator 512 and higher than the reference voltage VrefL inputted to the comparator 514, the erasure determination circuit 510 outputs the outputs of the comparators 512, 514 as “1”. As a result, the erasure determination circuit 510 outputs a control signal ER as “1”, and outputs a control signal BIT as “0”.

If the voltage SENS is not less than the reference voltage VrefH inputted to the comparator 512, the output of the comparator 512 is “0”, and the output of the comparator 514 is “1”. As a result, the erasure determination circuit 510 outputs the control signal ER as “0”, and outputs the control signal BIT as “1”.

If the voltage SENS is not more than the reference voltage VrefL inputted to the comparator 514, the output of the comparator 512 is “1”, and the output of the comparator 514 is “0”. As a result, the erasure determination circuit 510 outputs the control signal ER as “0”, and outputs the control signal BIT as “0”.

The erasure determination circuit 510 determines the state of data stored in the memory cell, and outputs the state of data by combining the 2-bit control signals ER and BIT. For example, the erasure determination circuit 510 can output the control signals (ER, BIT)=(1, 0) as the erasure state “*” determine (0, 1) as the inversion state “1”, and output (0, 0) as the normal state “0”.

By outputting the state of the bit of the memory cell 506 determined by the erasure determination circuit 510 to the input data reception circuit 10 in the error correction device 1, it is possible to achieve the semiconductor device for performing error correction according to the first embodiment.

FIG. 11 is a diagram showing a probability distribution with respect to the resistance value of the memory cell according to the first embodiment. FIG. 11 shows the relationship between a resistance value read after a low-resistance state is written to a low-resistance cell and the occurrence probability.

By setting threshold values a, b for the resistance value of the memory cell 506, the resistance value of the memory cell is read in the form of three values. More specifically, the threshold values a, b are set corresponding to the reference voltages VrefH, VrefL of the comparators 512, 514 in the erasure determination circuit 510, so that the erasure determination circuit 510 determines that the resistance value of the memory cell 506 not more than the threshold value a is in the normal state “0”, determines that the resistance value not less than the threshold value b is in the inversion state “1”, and determines that the resistance value more than the threshold value a and less than the threshold value b is in the erasure state “*”.

The erasure determination circuit 510 reads data stored in the memory cell 506 in the form of three values “*”, “1”, “0”, and outputs the result to the input data reception circuit 10 of the error correction device 1, so that the erasure determination circuit 510 can be used as the error correction device in memory data reading.

Next, an error occurrence probability using a general Hamming code and an error occurrence probability using the error correction method according to the first embodiment will be described.

Assume that Pp denotes the probability of the normal state “0”, Pf denotes the probability of the inversion state “1”, and Pe denotes the probability of the erasure state “*”. In this case, a relational expression of Pp+Pf+Pe=1 is established.

The probability Pc2 of an error in a general (n, k) Hamming code can be expressed by the following equation (1).

$$\begin{matrix}Pc 2 = ( 1 - allbit normal - 1 bit error ) \times d / n \\ = ( 1 - {Pp}^{n} - {Pp}^{n - 1} \times ( Pf + Pe ) \times n ) \times d / n\end{matrix} \qquad ( 1 )$$

The symbol d denotes an inter-code distance, and in the case of the Hamming code, d=3. In the equation (1), if (Pf+Pe)<<Pp, Pc2 is proportional to the square of (Pf+Pe). For example, in the case of the (7, 4) Hamming code, Pc2 is obtained by the following equation (2).

Pc2≈9×(Pf+Pe)² (2)

On the other hand, an error occurrence probability Pc3 using the error correction method according to the first embodiment is expressed by the following equation (3).

$$\begin{matrix}Pc 3 = ( \begin{matrix}1 - allbit normal - 1 bit inversion - 1 bit erasure - \\ 1 bit inversion and 1 bit erasure - 2 bit erasure\end{matrix} ) \times d / n \\ = ( \begin{matrix}1 - {Pp}^{n} - {Pp}^{n - 1} \times Pf \times n - {Pp}^{n - 1} \times Pe \times n - {Pp}^{n - 2} \times \\ Pe \times Pf \times n \times ( n - 1 ) - {Pp}^{n - 2} \times {Pe}^{2} \times n \times ( n - 1 ) / 2\end{matrix} ) \times d / n\end{matrix} \qquad ( 3 )$$

In the equation (3), if (Pf+Pe)<<Pp, Pc3 takes two kinds of values, depending on the relation between Pf and Pe, as shown in the following equations (4), (5).
In the case of Pf=Pe,

Pc3≈12×(Pf+Pe)² (4)
In the case of Pf<<Pe,

Pc3≈21×Pe³ (5)

In the case of Pf<<Pe, the error occurrence probability Pc3 is proportional to the cube of the probability Pe of the erasure state “*”. From this result, it is found that the error occurrence probability using the error correction method according to the first embodiment is lower than the error occurrence probability using the general Hamming code.

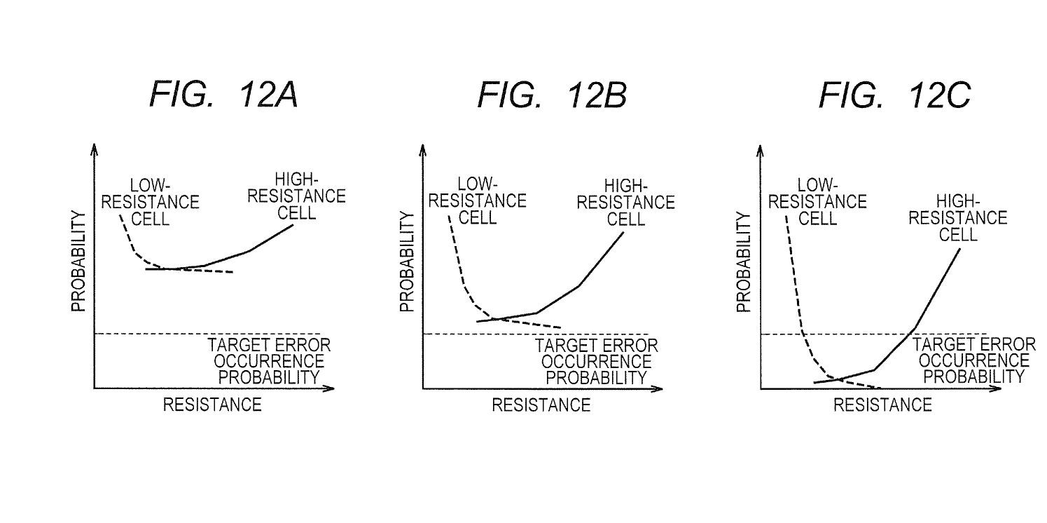

FIGS. 12A to 12C are diagrams for comparing error occurrence probabilities under different conditions according to the first embodiment. FIGS. 12A to 12C each show the relationship between a resistance value read after a low-resistance state is written to a low-resistance cell and a high-resistance state is written to a high-resistance cell and the occurrence probability.

FIG. 12A shows the relationship between the resistance value read from the cell without performing error correction and the occurrence probability. If a resistance value such that the occurrence probability falls below a target error occurrence probability is set as the resistance value of the boundary between the high resistance and the low resistance, it is possible to determine the high-resistance and low-resistance cells without error in reality. In FIG. 12A, there are distributed occurrence probabilities higher than the target error occurrence probability as the resistance in the low-resistance cell increases and as the resistance in the high-resistance cell decreases. However, there does not exist a resistance value such that both fall below the target error occurrence probability. Therefore, in the case of FIG. 12A of not performing error correction, it is not possible to perform determination without error in reality.

FIG. 12B shows the relationship between the resistance value read from the cell using the Hamming code and the occurrence probability. There are distributed occurrence probabilities slightly higher than the target error occurrence probability as the resistance in the low-resistance cell increases and as the resistance in the high-resistance cell decreases. However, there does not exist a resistance value such that both fall below the target error occurrence probability. Although the error occurrence probability decreases compared to the case of FIG. 12A of not performing error correction; in the case of FIG. 12B of performing error correction with the general Hamming code, it is not possible to perform determination without error in reality.

FIG. 12C shows the relationship between the resistance value read from the cell using the error correction method according to the first embodiment and the occurrence probability. There are distributed occurrence probabilities significantly lower than the target error occurrence probability as the resistance in the low-resistance cell increases and as the resistance in the high-resistance cell decreases. Accordingly, there exist resistance values such that both fall below the target error occurrence probability. Therefore, in the case of FIG. 12C of performing the error correction method according to the first embodiment, it is possible to perform determination without error in reality. According to the error correction method according to the first embodiment, it is possible to significantly decrease the error occurrence probability in spite of a simple configuration.

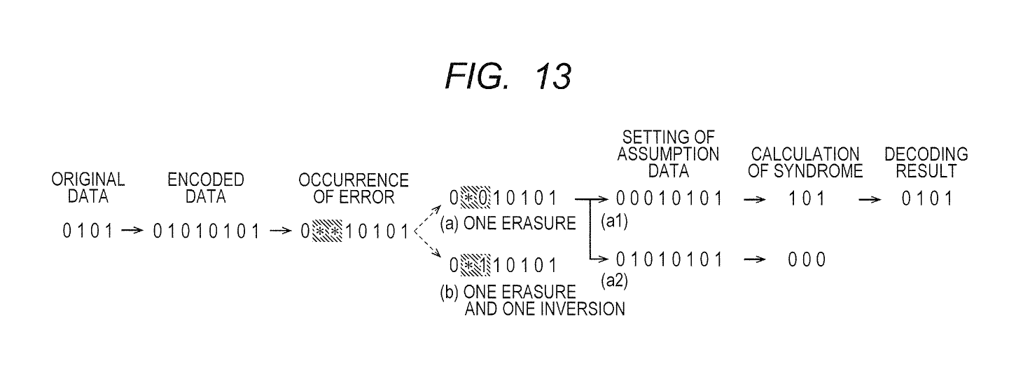

FIG. 13 is a diagram for explaining an error correction method for data encoded by the Hamming code and containing 2-bit erasure according to the first embodiment.

Referring to FIG. 13, 4-bit original data is encoded into a (8, 4) Hamming code. At this time, a parity bit is set so that the parity becomes even. Assume that an error occurs in the encoded data, which brings about encoded data containing 2-bit erasure.

First, in the error correction method according to this embodiment, one of the erased two bits is set to “0” or “1”. For example, in (a) of FIG. 13, the erased third bit is set to “0”. Next, in the error correction method according to this embodiment, the second bit is set as the erasure bit, and assumption data for a case where the erasure bit is “0” as in (a1) of FIG. 13 and assumption data for a case where the erasure bit is “1” as in (a2) of FIG. 13 are set. At this time, it is unknown whether or not inversion is contained in each assumption data.

Next, in the error correction method according to this embodiment, a syndrome is calculated for each set assumption data, thereby to decode the original data. At this time, all elements of the syndrome of the assumption data in which the erasure bit is assumed to be “1” in (a2) of FIG. 13 are 0; therefore, the result decoded based on the applicable assumption data is adopted. Alternatively, the result decoded based on the syndrome result of the assumption data in which the erasure bit is assumed to be “0” in (a1) of FIG. 13 may be adopted.

On the other hand, in the case where the erased third bit is set to “1” in (b) of FIG. 13, the third bit indicates inversion, and the encoded data contains 1-bit inversion and 1-bit erasure. This can be corrected by the error correction method according to the first embodiment; therefore, detailed description will not be repeated.

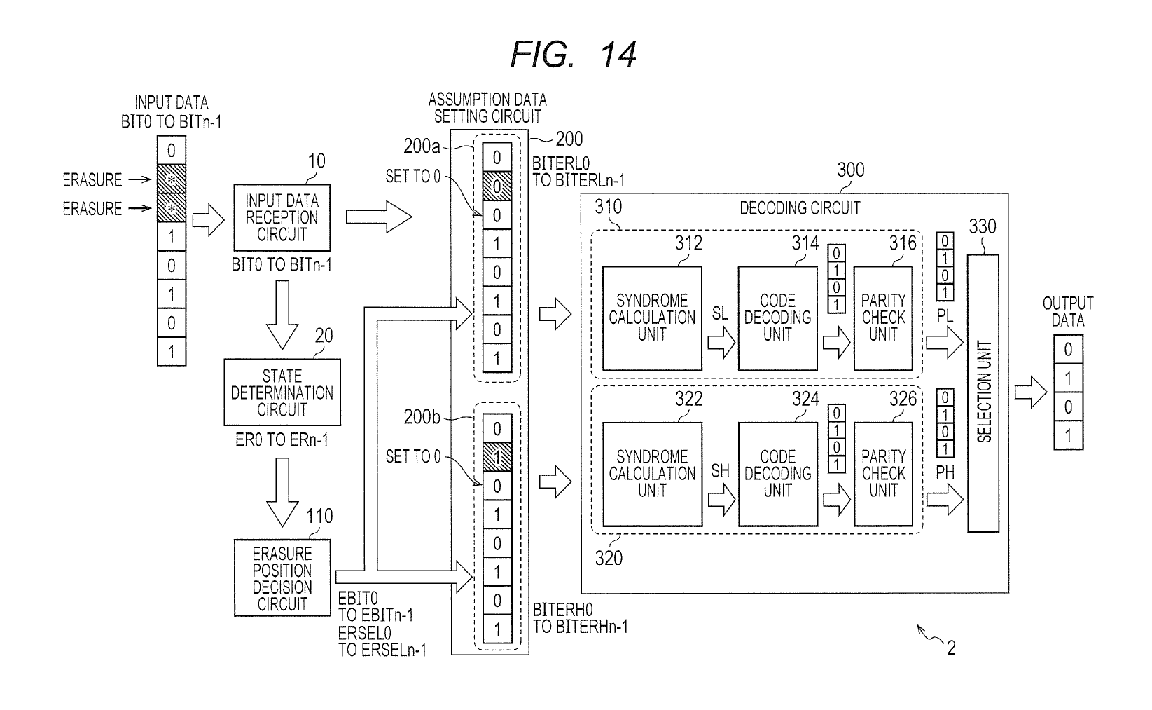

Thus, it is possible to improve the correction capability of the error correction code with a simple method. FIG. 14 is a diagram showing a configuration example of an error correction device according to a modification of the first embodiment.

The error correction device 2 which implements the error correction method according to this embodiment will be described. Only differences with the error correction device 1 according to the first embodiment will be described, and the overlapping contents will not be repeated.

Referring to FIG. 14, assume that the input data BIT0 to BIT7 (0**10101) is inputted to the input data reception circuit 10. The state determination circuit 20 outputs the erasure state determination data ER0 to ER7 (01100000).

In this example, the erasure position decision circuit 100 is changed to an erasure position decision circuit 110. In comparison with the erasure position decision circuit 100, the erasure position decision circuit 110 decides an erasure bit position and sets setting data. More specifically, the erasure position decision circuit 110 sets the second bit as the erasure bit, based on predetermined priority order.

Further, the erasure position decision circuit 110 generates setting data for setting (fixing) to either “0” or “1” a bit in which the erasure position decision data ERSELk is set as “0” (non-erasure bit) due to low priority or the like though the erasure state determination data ERk indicates “1” (erasure state).

More specifically, if the erasure state determination data ERk indicates “0” (non-erasure state), the erasure position decision circuit 110 outputs setting data EBITk (“0”) to set the input data BITk as it is. On the other hand, if the erasure state determination data ERk indicates “1” (erasure state) and the erasure position decision data ERSELk indicates “0” (not set as the erasure bit), the erasure position decision circuit 110 outputs setting data EBITk (“1”) to set the input data BITk to either “0” or “1”.

As for whether to set the input data BITk to either “0” or “1”, either value may be determined beforehand.

In the example of FIG. 14, the erasure state determination data ER2 is “1” (erasure state) and the erasure position decision data ERSEL2 is “0” (non-erasure bit); accordingly, the erasure position decision circuit 110 sets the setting data EBIT2 to “1” based on predetermined setting.

Therefore, the erasure position decision circuit 110 outputs the erasure position decision data ERSEL0 to ERSEL7 (01000000) and the setting data EBIT0 to EBIT7 (00100000) to the assumption data setting circuit 200.

Based on the input data BIT0 to BIT7 (0**10101) inputted to the input data reception circuit 10, the erasure position decision data ERSEL0 to ERSEL7 (01000000) inputted from the erasure position decision circuit 110, and the setting data EBIT0 to EBIT7 (00100000), the assumption data setting circuit 200 sets assumption data for a case where the erasure bit is “0” and assumption data for a case where the erasure bit is “1”.

More specifically, the input data BIT0 to BIT7 (0**10101) is converted into the input data BIT0 to BIT7 (0*010101), in accordance with the setting data EBIT0 to EBIT7 (00100000). The setting data EBITk (“1”) in this example fixes the corresponding bit to 0 as an example.

The AND gate 204 receives the input data BIT0 to BIT7 (0*010101) and the input of the erasure position decision data ERSEL0 to ERSEL7 (01000000) inverted through the inverter 202, and sets the AND logical operation result as the assumption data BITERL0 to BITERL7 (00010101).

On the other hand, the OR gate 206 receives the input data BIT0 to BIT7 (0*010101) and the input of the erasure position decision data ERSEL0 to ERSEL7 (01000000), and sets the OR logical operation result as the assumption data BITERH0 to BITERH7 (01010101).

Thus, it is possible to achieve the error correction device that improves the correction capability of the error correction code with a simple configuration.

### Second Embodiment

### [Error Correction in the Case of Representing Each Bit in the Form of Four Values]

In the first embodiment, as seen in the equation (5), to decrease the error occurrence probability, it is required that the probability Pe of the erasure state “*” is higher than the probability Pf of the inversion state “1”.

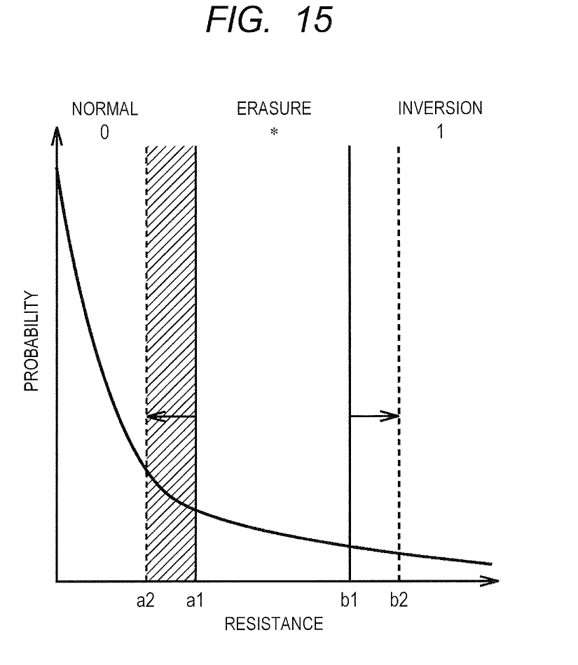

FIG. 15 is a diagram showing a probability distribution with respect to the resistance value of the memory cell according to the second embodiment. Referring to FIG. 15, by extending the range of resistance values of the memory cell corresponding to the erasure state from a1-b1 to a2-b2, it is possible to increase the probability Pe of the erasure state “*” and decrease the probability Pf of the inversion state “1”. However, in the case of extending the range of resistance values of the memory cell corresponding to the erasure state, a range that is originally treated as the normal state “0” is treated as the erasure state “*” (diagonally shaded area in FIG. 15).

In this case, if the number of erasure bits in encoded data falls below the erasure correction capability of the error correction code, the error occurrence probability does not increase; however, if the number of erasure bits exceeds the erasure correction capability, the error occurrence probability increases.

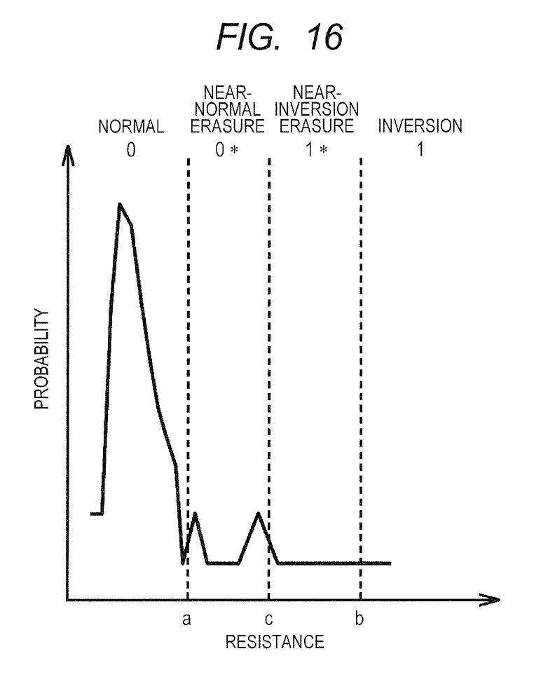

FIG. 16 is a diagram showing a probability distribution with respect to the resistance value of the memory cell according to the second embodiment. Referring to FIG. 16, although two threshold values are provided for the resistance value of the memory cell in the first embodiment, three threshold values are provided for the resistance value of the memory cell in this embodiment, thereby reading the resistance value of the memory cell in the form of four values. More specifically, in determining the state of the bit stored in the memory cell, the erasure determination circuit determines that the resistance value of the memory cell not more than the threshold value a is in the normal state “0”, determines that the resistance value not less than the threshold value b is in the inversion state “1”, determines that the resistance value more than the threshold value a and not more than the threshold value c is in a near-normal erasure state “0*”, and determines that the resistance value more than the threshold value c and not more than the threshold value b is in a near-inversion erasure state “1*”.

In this embodiment, even in the case of extending the resistance threshold range a-b of the memory cell; due to the determination of the near-normal erasure state “0” from the normal state “0”, it is possible to prevent an increase in the error occurrence probability.

An error occurrence probability Pc4, using an error correction method in which each bit of encoded data is represented in the form of four values, is expressed by the following equation (6). Pep denotes the probability of near-normal erasure, and Pef denotes the probability of near-inversion erasure.

$$\begin{matrix}Pc 4 = 1 - allbit normal - 1 bit inversion - 1 bit erasure - \\ 2 bit erasure - 1 bit inversion and 1 bit erasure - \\ 2 bit erasure and 1 bit nearnormal erasure - \\ 1 bit erasure and 1 bit inversion and 1 bit nearnormal erasure \\ = 1 - {Pp}^{( n + 1 )} - {Pp}^{n} \times Pf \times ( n + 1 ) - {Pp}^{n} \times Pe \times ( n + 1 ) - {Pp}^{( n - 1 )} \times \\ {Pe}^{2} \times ( n + 1 ) \times n / 2 - {Pp}^{( n - 1 )} \times Pe \times Pf \times ( n + 1 ) \times n - {Pp}^{( n - 1 )} \times \\ Pe \times Pf \times Pep \times ( n + 1 ) \times n \times ( n - 1 ) / 2 - {Pp}^{( n - 2 )} \times Pe \times Pe \times \\ Pep \times ( n + 1 ) \times n \times ( n - 1 ) / 6\end{matrix} \qquad ( 6 )$$

In the case of Pf<<Pe in the equation (6), Pc4 is expressed by the following equation (7).

c4=Pc3×Pef/Pe (7)

Therefore, in the case of extending the resistance threshold range a-b of the memory cell in the erasure state and Pf<<Pe; by representing each bit of encoded data in the form of four values, it is possible to decrease the error occurrence probability in comparison with the case of representing each bit of encoded data in the form of three values.

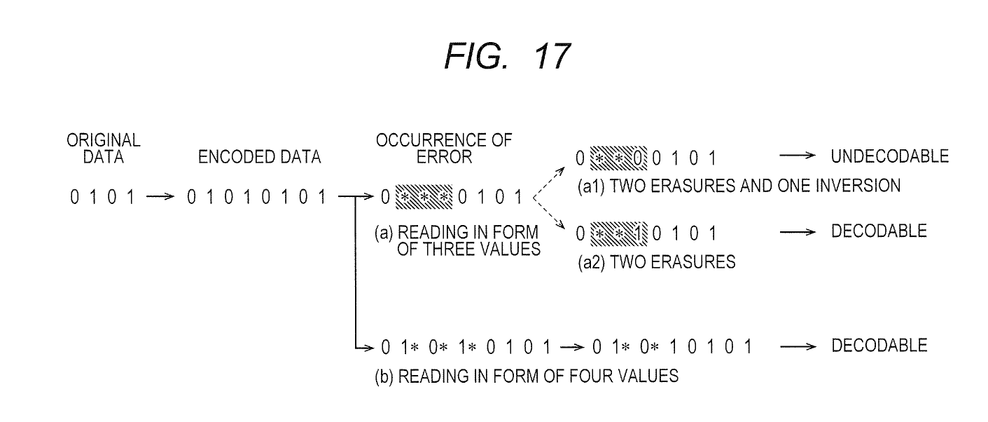

FIG. 17 is a diagram for explaining an error correction method for a Hamming code containing 3-bit erasure according to the second embodiment. Referring to FIG. 17, 4-bit original data is encoded into a (8, 4) Hamming code. At this time, a parity bit is set for even parity. Assume that an error occurs in the encoded data, which brings about encoded data containing 3-bit erasure (including near-normal erasure and near-inversion erasure).

In the error correction method according to this embodiment, the encoded data contains three erasure bits, whereas the Hamming code has the capability of erasure correction of up to two bits; accordingly, one of the three bits indicating the erasure state is set to either “0” or “1”.

In (a) of FIG. 17, in the case of representing the state of each bit in the form of the three values of the normal state “0”, the erasure state “*”, and the inversion state “1”, the probability of correctness of the value of “0” or “1” to be set is ½. More specifically, in the case where the fourth bit is set to “0” in (a1) of FIG. 17, the encoded data contains 2-bit erasure and 1-bit inversion, which is beyond the range of the correction capability of the Hamming code, and is therefore undecodable. On the other hand, in the case where the fourth bit is set to “1” in (a2) of FIG. 17, the encoded data contains 2-bit erasure, which enables the application of the error correction method of the Hamming code containing 2-bit erasure, and is therefore decodable.

The case of representing each bit in the form of four values as the error correction method according to second embodiment will be described.

In (b) of FIG. 17, in the case of representing the state of each bit of encoded data in the form of the four values of the normal state “0”, the near-normal erasure state “0”, the near-inversion erasure state “1*”, and the inversion state “1”, one bit to be set to “0” or “1” is set to “0” if it is “0*”, and set to “1” if it is “1*”. In consideration of whether the bit in the erasure state is near the normal state or near the inversion state, either “0” or “1” is set.

In this case, the second to fourth bits of the encoded data are indicated as the near-inversion erasure state “1*”, the near-normal erasure state “0*”, and the near-inversion erasure state “1*”.

Accordingly, by way of example, in the second embodiment, one of these bits is fixed. For example, the fourth bit in the erasure state is set (fixed) to “1” due to the near-inversion erasure state “1*”.

Further, the remaining second and third bits in the erasure state undergo decoding processing in which assumption data is set by the same method as described above.

By this processing, in the case of representing encoded data in the form of four values, the possibility of decoding increases in comparison with the case of representing each bit of encoded data in the form of three values.

By representing each bit of encoded data in the form of four values, even if the probability Pe of the erasure state (including near-normal erasure and near-inversion erasure) is increased, the error occurrence probability does not increase. Further, it is possible to improve the original correction capability of the error correction code with a simple configuration.

A semiconductor storage device according to the second embodiment will be described. Only differences with the semiconductor storage device 5 according to the first embodiment will be described, and the overlapping contents will not be described in detail.

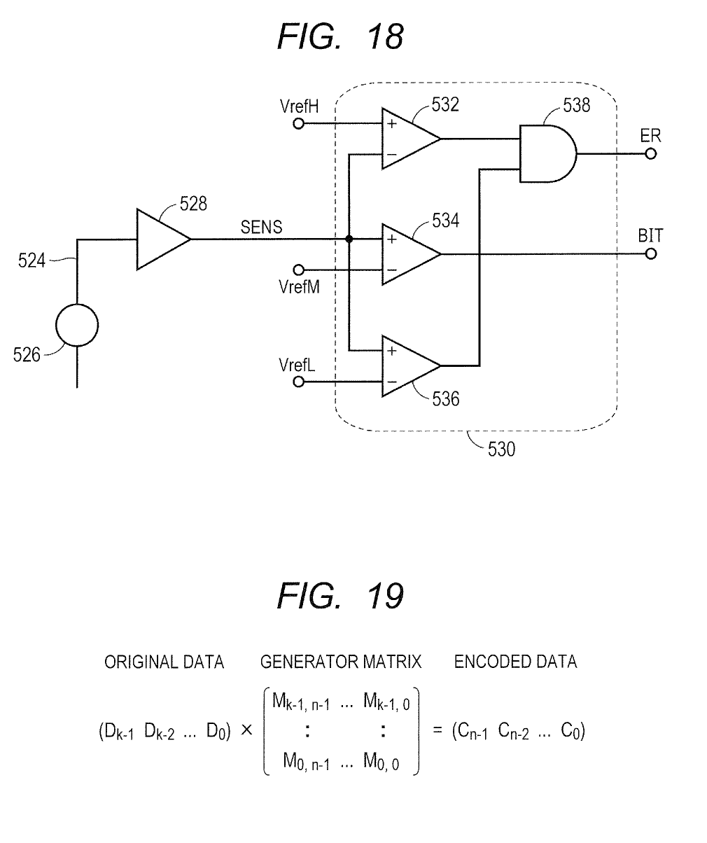

FIG. 18 is a diagram for explaining a circuit configuration example of an erasure determination circuit according to the second embodiment. The erasure determination circuit 530 is a circuit for reading the state of the bit stored in a memory cell 526. The erasure determination circuit 530 according to this embodiment includes comparators 532, 534, 536, and an AND gate 538.

A sense amplifier 528 outputs a voltage SENS according to the data level of the memory cell 526 read from a bit line 524. The erasure determination circuit 530 compares the voltage SENS with reference voltages VrefH, VrefM, VrefL inputted to the comparators 532, 534, 536, thereby determining the state of the bit stored in the memory cell 526. Assume that the voltage value VrefH>VrefM>VrefL.

More specifically, if the voltage SENS outputted from the sense amplifier 528 is lower than the reference voltage VrefH inputted to the comparator 532 and higher than the reference voltage VrefM inputted to the comparator 534, the erasure determination circuit 530 outputs the outputs of the comparators 532, 534, 536 as “1”. As a result, the erasure determination circuit 530 outputs a control signal ER as “1”, and outputs a control signal BIT as “1”.

If the voltage SENS outputted from the sense amplifier 528 is not more than the reference voltage VrefM inputted to the comparator 534 and higher than the reference voltage VrefL inputted to the comparator 536, the outputs of the comparators 532, 536 are. “1”, and the output of the comparator 534 is “0”. As a result, the erasure determination circuit 530 outputs the control signal ER as “1”, and outputs the control signal BIT as “0”.

If the voltage SENS is not less than the reference voltage VrefH inputted to the comparator 532, the output of the comparator 532 is “0”, and the outputs of the comparators 534, 536 are “1”. As a result, the erasure determination circuit 530 outputs the control signal ER as “0”, and outputs the control signal BIT as “1”.

If the voltage SENS is not more than the reference voltage VrefL inputted to the comparator 536, the output of the comparator 532 is “1”, and the outputs of the comparators 534, 536 are “0”. As a result, the erasure determination circuit 530 outputs the control signal ER as “0”, and outputs the control signal BIT as “0”.

The erasure determination circuit 530 determines the state of data stored in the memory cell, and can output the state of data by combining the 2-bit control signals ER and BIT. For example, the erasure determination circuit 530 can output the control signals (ER, BIT)=(1, 0) as the near-normal erasure state “0*”, output (1, 1) as the near-inversion erasure state “1*”, output (0, 0) as the normal state “0”, and output (0, 1) as the inversion state “1”.

The erasure determination circuit 530 reads data stored in the memory cell 526 in the form of four values “0*”, “1*”, “0”, “1”, and outputs the result to the input data reception circuit 10 of the error correction device 2, so that the erasure determination circuit 530 can be used as the error correction device in memory data reading.

More specifically, in the case of occurrence of 3-bit erasure in the encoded data, one of the erasure bits is fixed by determining which state the erasure is near. This leads to 2-bit erasure.

Then, the 2-bit erasure can undergo decoding processing based on the method described with FIG. 14.

By this processing, by the error correction method according to second embodiment, even in the case of occurrence of 3-bit erasure, by setting “0” or “1” in consideration of whether the bit in the erasure state is near the normal state or near the inversion state, it is possible to achieve the error correction device having a high possibility of decoding, in comparison with the case of representing each bit of encoded data in the form of three values.

### Third Embodiment

### [Error Correction Using BCH Code]

FIG. 19 is a diagram for explaining an example of data encoding using a BCH code.

Assume that the bit length of original data is k and the bit length of encoded data is n. It is possible to generate n-bit BCH encoded data by multiplying original data by a generator matrix. The inter-code distances d of BCH codes are 3, 5, 7, and so on, depending on used generator matrices. The BCH codes whose inter-code distances are 3, 5, 7 can correct errors of 1, 2, 3 bits, respectively.

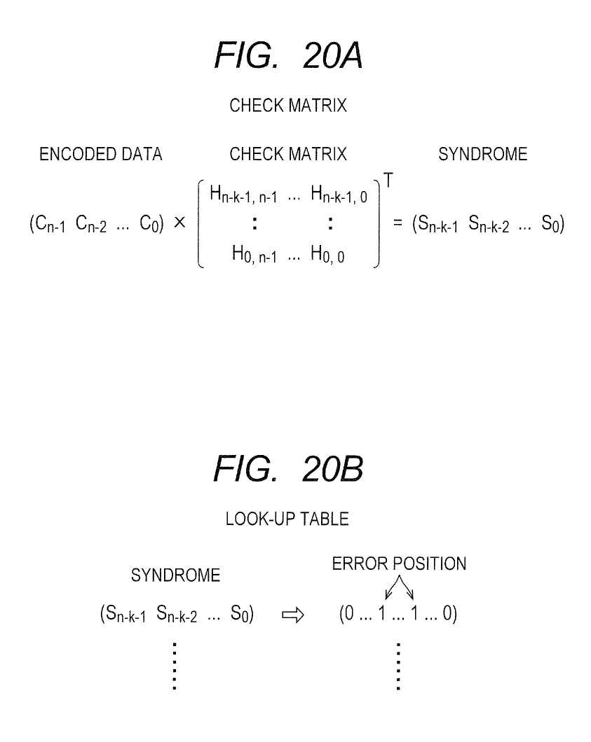

FIGS. 20A and 20B are diagrams for explaining an error detection method and an error correction method for data encoded by the BCH code.

Although there exist various methods for decoding data encoded by the BCH code; by way of example, a method using a look-up table as shown in FIG. 20B will be described. This method is effective in the case where high-speed decoding is required, such as in a memory.

Referring to FIG. 20A, first, in the error correction using the BCH code, the encoded data is multiplied by the transposed matrix of a check matrix, thereby calculating a syndrome. In the case of the BCH code, the number of errors (including inversion and erasure) and the error position uniquely correspond to the syndrome. Therefore, by comparing the calculated syndrome with a prepared look-up table in which each syndrome and each error position are combined, it is possible to specify the number of errors and the error position. It is possible to decode the original data based on the comparison result by the method using the look-up table.

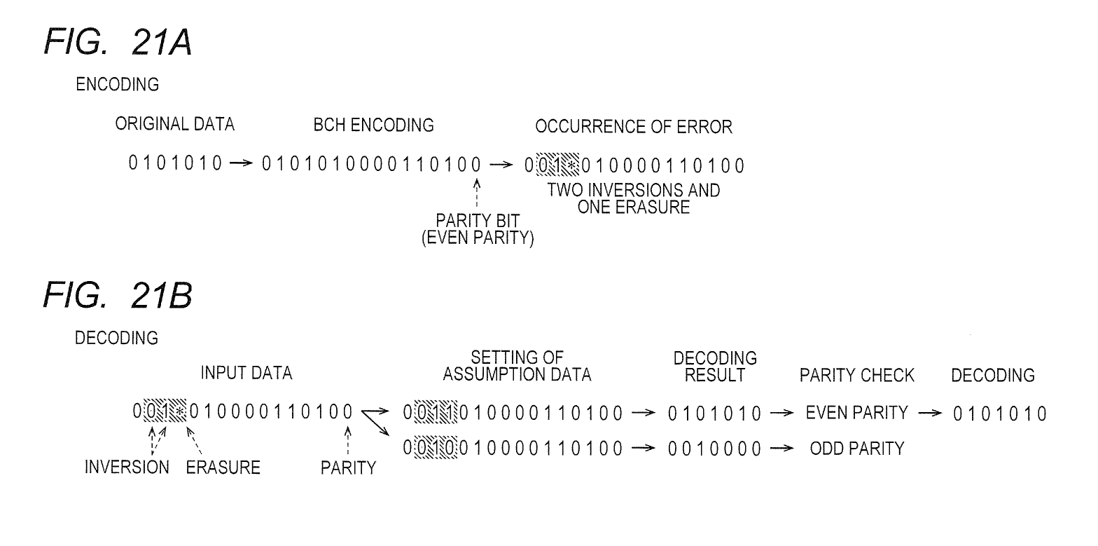

FIGS. 21A and 21B are diagrams for explaining an error correction method for data encoded by the BCH code and containing 1-bit erasure and 2-bit inversion according to the third embodiment. Referring to FIG. 21A, by way of example, 7-bit original data is encoded into a (15, 7) BCH code, and one parity bit is added so that the parity becomes even. Assume that an error occurs in the encoded data, which brings about encoded data containing 2-bit inversion and 1-bit erasure.

Referring to FIG. 21B, to decode the original data, assumption data for a case where the erasure bit of input data is “0” and assumption data for a case where the erasure bit is “1” are set. At this time, it is unknown whether or not inversion is contained in each assumption data.

Next, in the error correction method according to the third embodiment, each set assumption data is multiplied by the check matrix, thereby calculating a syndrome. The syndrome is compared with the look-up table prepared beforehand, thereby specifying the number of inversions and the position in the assumption data and decoding the original data.

Since the (15, 7) BCH code has the capability of inversion correction of up to two bits, 2-bit inversion and 3-bit inversion cannot be distinguished, and each assumption data is determined to contain 2-bit inversion.

Next, in the error correction method according to the third embodiment, a parity check is performed on each set assumption data. Since the original encoded data is set so that the parity becomes even, it is determined that 2-bit inversion is contained if the parity of the assumption data is even and 3-bit inversion is contained if the parity of the assumption data is odd. Accordingly, it is determined that the assumption data of even parity which is within the range of the error correction capability of the (15, 7) BCH code is correct assumption data, and the result decoded using the applicable assumption data is adopted.

According to the third embodiment, it is possible to improve the correction capability of the error correction code with a simple method.

The error correction device according to the third embodiment will be described. Only differences with the error correction device 1 according to the first embodiment will be described, and the overlapping contents will not be described in detail.

The code decoding unit 314 compares the syndrome SL calculated by the syndrome calculation unit 312 with the look-up table stored beforehand, thereby specifying the error position and decoding the decoding result based on the assumption data BITERL0 to BITERLn-1 set by the assumption data setting unit 200a.

The code decoding unit 324 compares the syndrome SH calculated by the syndrome calculation unit 322 with the look-up table stored beforehand, thereby specifying the error position and decoding the decoding result based on the assumption data BITERH0 to BITERHn-1 set by the assumption data setting unit 200b.

Thus, it is possible to achieve the error correction device that implements the error correction method using the BCH code according to the third embodiment.

While the invention made above by the present inventors has been described specifically based on the illustrated embodiments, the present invention is not limited thereto. It is needless to say that various changes and modifications can be made thereto without departing from the spirit and scope of the invention.

What is claimed is:

1. An error correction device which can perform c (c<n) error corrections on n-bit encoded data containing a parity bit, the error correction device comprising:
an assumption data setting circuit for setting a plurality of assumption data by assuming data of an erasure bit in encoded data containing c or fewer error bits and (n−c) or fewer bits which cannot be determined to be 0 or 1, that is, erasure bits; and
a decoding circuit which calculates a syndrome for each of the assumption data set by the assumption data setting circuit and performs decoding based on a calculation result and the parity bit.

2. The error correction device according to claim 1, wherein the decoding circuit selects one of decoding results for the assumption data, based on the parity bit.

3. The error correction device according to claim 1, wherein the decoding circuit selects and decodes one of the assumption data, based on the calculation result and the parity bit.

4. The error correction device according to claim 1, wherein each bit of the n-bit encoded data is represented as three-value or four-value data.

5. The error correction device according to claim 4,
wherein the three-value or four-value data is represented by two bits,
wherein one of the two bits indicates a magnitude of a data value of a corresponding bit of the encoded data, and
wherein the other of the two bits indicates whether or not a corresponding bit of the encoded data is an erasure bit.

6. The error correction device according to claim 1, wherein the assumption data setting circuit sets a plurality of assumption data in accordance with predetermined priority.

7. The error correction device according to claim 1, further comprising an erasure position decision circuit for deciding a position of the erasure bit in the encoded data.

8. The error correction device according to claim 1,
wherein the assumption data setting circuit comprises a plurality of assumption data setting units, operating in parallel with each other, according to the number of correctable erasure bits, and
wherein the decoding circuit comprises a plurality of decoding units which are provided corresponding respectively to the assumption data setting units and decode set assumption data.

9. The error correction device according to claim 1,
wherein the assumption data setting circuit comprises assumption data setting units whose number is a power of the number of correctable erasure bits, and
wherein the assumption data setting units set different assumption data respectively, based on a combination of assumed values of erasure bits.

10. The error correction device according to claim 1, wherein the decoding circuit performs a parity check on the assumption data.

11. The error correction device according to claim 1, wherein the decoding circuit performs Hamming decoding or BCH decoding.

12. A semiconductor storage device comprising:
a plurality of storage elements for storing n-bit encoded data containing a parity bit;
a read circuit for reading encoded data stored in the storage elements; and
an error correction circuit which can perform c (c<n) error corrections on encoded data read by the read circuit,
wherein the error correction circuit comprises
an assumption data setting circuit for setting a plurality of assumption data by assuming data of an erasure bit in encoded data containing c or fewer error bits and at least one erasure bit, and
a decoding circuit which calculates a syndrome for each of the assumption data set by the assumption data setting circuit and performs decoding based on a calculation result and the parity bit.

13. The semiconductor storage device according to claim 12, wherein the read circuit reads the encoded data, based on comparison of a voltage according to data stored in each storage element with a reference voltage to be compared.

14. The semiconductor storage device according to claim 12, wherein encoded data stored in the storage element is a resistance value, a charge amount, a voltage value, or a current value stored in an SRAM, a DRAM, a flash memory, an ReRAM, an MRAM, or an FeRAM.

15. An error correction method which can perform c (c<n) error corrections on n-bit encoded data containing a parity bit, the error correction method comprising the steps of:
setting a plurality of assumption data by assuming data of an erasure bit in encoded data containing c or fewer error bits and at least one erasure bit;
calculating a syndrome for each of the assumption data; and
performing decoding based on the calculated syndrome and the parity bit.
